(19) United States
(12) Patent Application Publication
(10) Pub. No.: US 2024/0237232 A1
(43) Pub. Date: Jul. 11, 2024

(54) CIRCUIT BOARD AND MANUFACTURING METHOD THEREOF, AND LIGHT EMITTING MODULE

(71) Applicant: HannStar Display Corporation, Taipei City (TW)

(72) Inventors: Pei-Hao Hung, Taichung City (TW); Chun I Chu, Hsinchu County (TW); Chia Lin Liu, Taichung City (TW); Yung-Li Huang, Tainan City (TW)

(73) Assignee: HannStar Display Corporation, Taipei City (TW)

(21) Appl. No.: 18/314,144

(22) Filed: May 9, 2023

(30) Foreign Application Priority Data
Jan. 9, 2023 (CN) 202310025285.3
Jan. 9, 2023 (CN) 202310025299.5

(51) Int. Cl. H05K 3/46; H05K 1/02; H05K 3/16; H05K 3/18; H05K 3/28

(52) U.S. Cl. CPC H05K 3/4644; H05K 1/0298; H05K 3/16; H05K 3/188; H05K 3/284; H05K 2201/10106; H05K 2201/2081; H05K 2203/05

(57) ABSTRACT

A circuit board including a substrate, a first circuit layer, a first insulating layer, a second circuit layer, and a solder resist layer is provided. The first circuit layer is disposed on the substrate. The first insulating layer is disposed on the substrate and covers a portion of the first circuit layer. The second circuit layer is disposed on the first insulating layer and penetrates a portion of the first insulating layer to electrically connect the first circuit layer. The solder resist layer is disposed on the substrate and covers a portion of the second circuit layer.

### CROSS-REFERENCE TO RELATED APPLICATION

This application claims the priority benefits of China application serial no. 202310025285.3, filed on Jan. 9, 2023 and China application Ser. No. 20/231,0025299.5, filed on Jan. 9, 2023. The entirety of each of the above-mentioned patent applications is hereby incorporated by reference herein and made a part of this specification.

### BACKGROUND

### Technical Field

The disclosure relates to an electronic component and a manufacturing method thereof, particularly to a circuit board, a light emitting module including the circuit board and a manufacturing method thereof.

### Description of Related Art

A light emitting module usually includes a corresponding circuit board. Therefore, the quality of the circuit board or the manufacturing method thereof often also has a certain impact on the light emitting module.

### SUMMARY

According to an embodiment of the disclosure, a manufacturing method of a circuit board includes the following steps: providing a substrate structure, wherein the substrate structure comprises a substrate and a first circuit layer disposed on the substrate; forming a first insulating layer on the substrate, wherein the first insulating layer has an insulating opening exposing a portion of the first circuit layer; forming a first conductive layer on the substrate, wherein the first conductive layer covers the first insulating layer having the insulating opening and the portion of the first circuit layer exposed by the insulating opening; forming a second insulating layer on the first conductive layer, wherein the first conductive layer has a first portion and a second portion, the first portion does not overlap the second insulating layer, and the second portion overlaps the second insulating layer; forming a second conductive layer on the first portion; removing the second insulating layer and the second portion, the first portion and the second conductive layer forming a second circuit layer; and forming a solder resist layer on the second circuit layer, wherein the solder resist layer has a solder resist opening exposing a portion of the second circuit layer.

According to an embodiment of the disclosure, a circuit board includes a substrate, a first circuit layer, a first insulating layer, a second circuit layer, and a solder resist layer. The first circuit layer is disposed on the substrate. The first insulating layer is disposed on the substrate and covers a portion of the first circuit layer. The second circuit layer is disposed on the first insulating layer and penetrates a portion of the first insulating layer to electrically connect the first circuit layer. The solder resist layer is disposed on the substrate and covers a portion of the second circuit layer.

According to an embodiment of the disclosure, a light emitting module includes a substrate, a first circuit layer, a first insulating layer, a second circuit layer, a solder resist layer, and a light-emitting device. The first circuit layer is disposed on the substrate. The first insulating layer is disposed on the substrate and covers a portion of the first circuit layer. The second circuit layer is disposed on the first insulating layer and penetrates a portion of the first insulating layer to electrically connect the first circuit layer. The solder resist layer is disposed on the substrate and covers a portion of the second circuit layer. The light-emitting device is disposed on the substrate and electrically connects to the second circuit layer.

Several exemplary embodiments accompanied with figures are described in detail below to further describe the disclosure in details.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1M are schematic side views of a portion of a manufacturing method of a circuit board according to an embodiment of the disclosure.

FIG. 2 is schematic a side view of a portion of a manufacturing method of a light emitting module according to an embodiment of the disclosure.

FIG. 3A to FIG. 3L are schematic side views of a portion of a manufacturing method of a circuit board according to an embodiment of the disclosure.

FIG. 4 is schematic a side view of a portion of a manufacturing method of a light emitting module according to an embodiment of the disclosure.

### DESCRIPTION OF THE EMBODIMENTS

Reference will now be made in detail to the present preferred embodiments of the invention, examples of which are illustrated in the accompanying drawings. As those skilled in the art would realize, the described embodiments may be modified in various different ways without departing from the spirit or scope of the invention.

In addition, relative terms such as “bottom” and “top” may be used for describing a relationship of one element and another element as that shown in the figures. It should be noted that the relative terms are intended to include a different orientation of the apparatus besides the orientation shown in the figure.

Unless explicitly stated otherwise, any process described herein shall not to be construed as to be performed in a particular order.

The terminology used herein is for the purpose of describing particular embodiments and is not intended to be limiting of the invention. As used herein, the singular forms “a” “an” and “the” are intended to include the plural forms as well, unless the context clearly indicates otherwise. “or” represents “and/or”. The term “and/or” used herein includes any or a combination of one or more of the associated listed items. It will be further understood that the terms “comprises,” “comprising,” “includes” and/or “including,” when used herein, specify the presence of stated features, regions, integers, steps, operations, elements, and/or components, but do not preclude the presence or addition of one or more other features, regions, integers, steps, operations, elements, components, and/or groups thereof.

In the drawings, a thickness or a size of each element, etc., is exaggerated for clarity's sake. Throughout the specification, the same reference numerals denote the same elements. It should be understood that when an element such as a layer, a film, a region, or a substrate is referred to as being “on another element”, or “connected to another element”, or “overlapped with another element”, it may be directly on the another element or connected to the another element, or intermediate elements may exist there between. Conversely, when an element is referred to as being “directly on another element” or “directly connected to another element”, there is no intermediate element.

It should be understood that although the terms “first”, “second”, “third”, etc., may be used to describe various elements, components, regions, layers and/or portions, these elements, components, regions, and/or portions are not restricted by these terms. These terms are only used to distinguish one element, component, region, layer or portion from another element, component, region, layer or portion. Therefore, the “first element”, “component,” “region,” “layer,” or “portion” discussed below may be referred to as a second element, component, region, layer or portion without departing from the teachings of the specification.

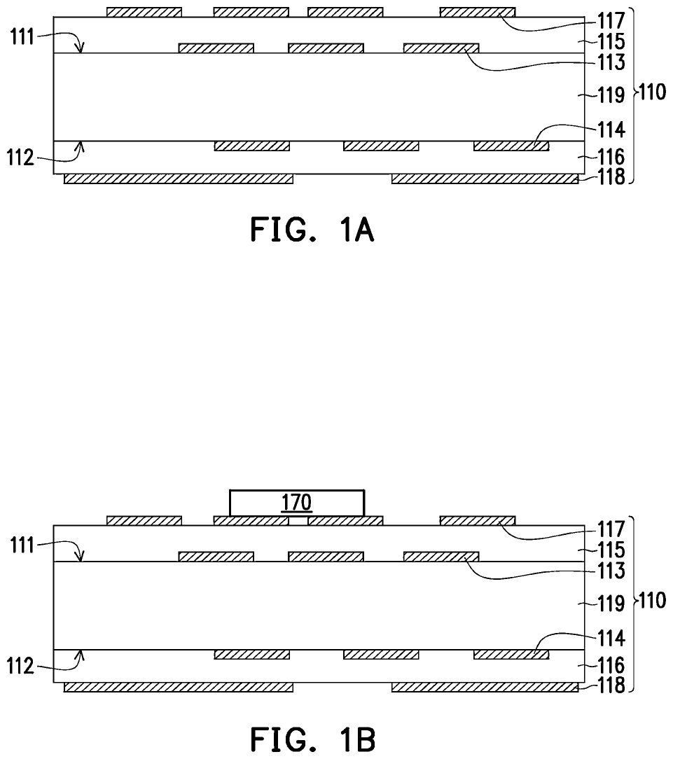

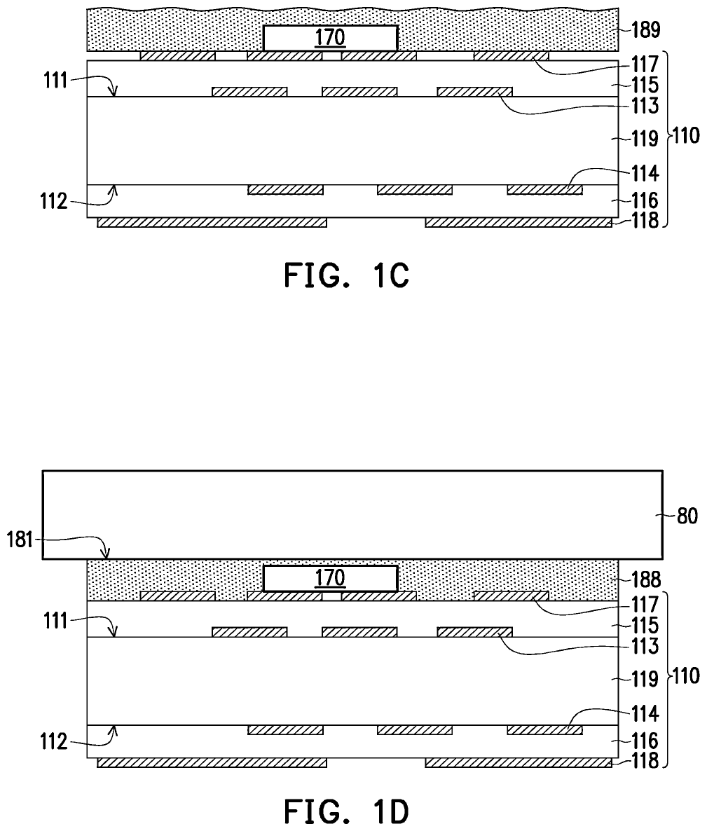

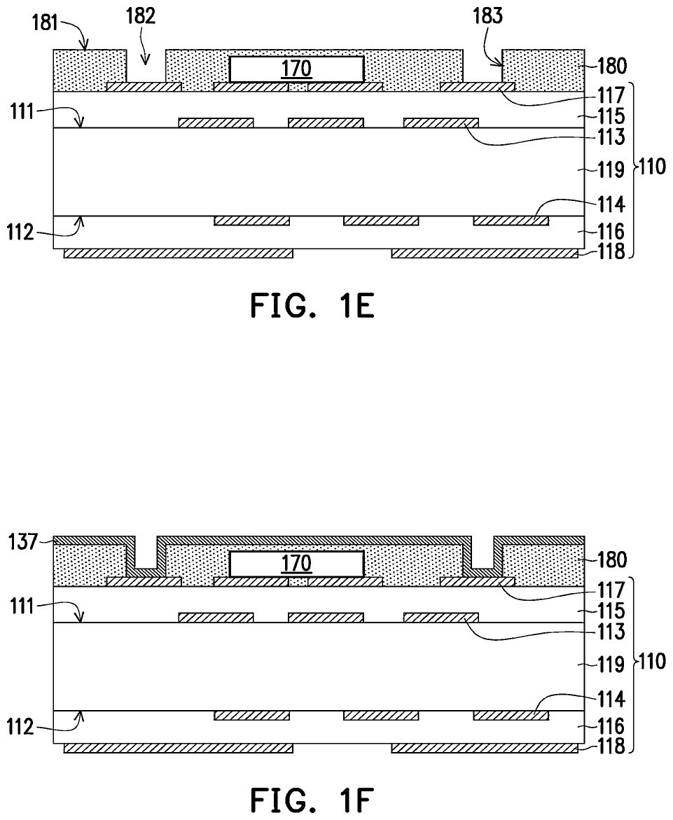

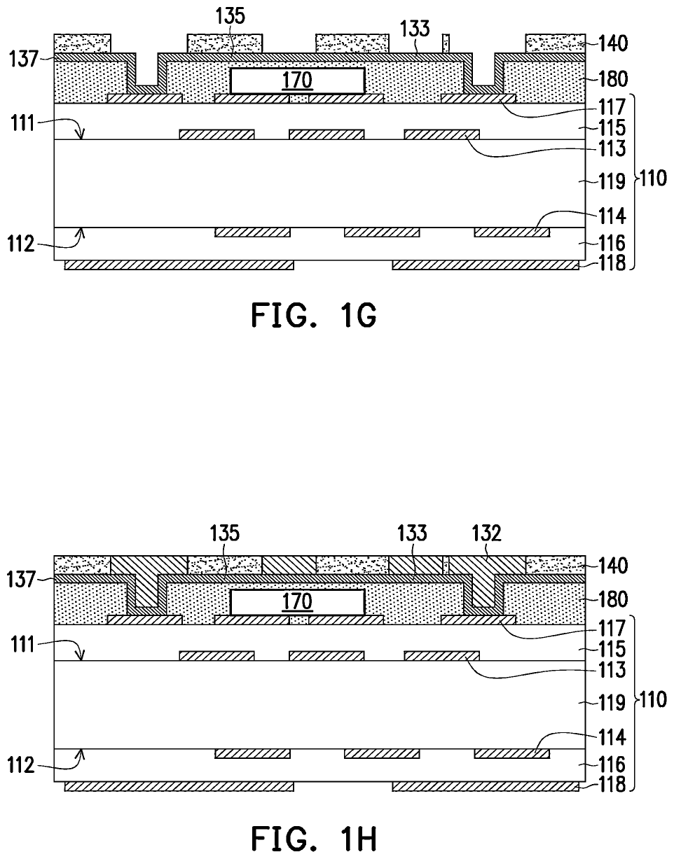

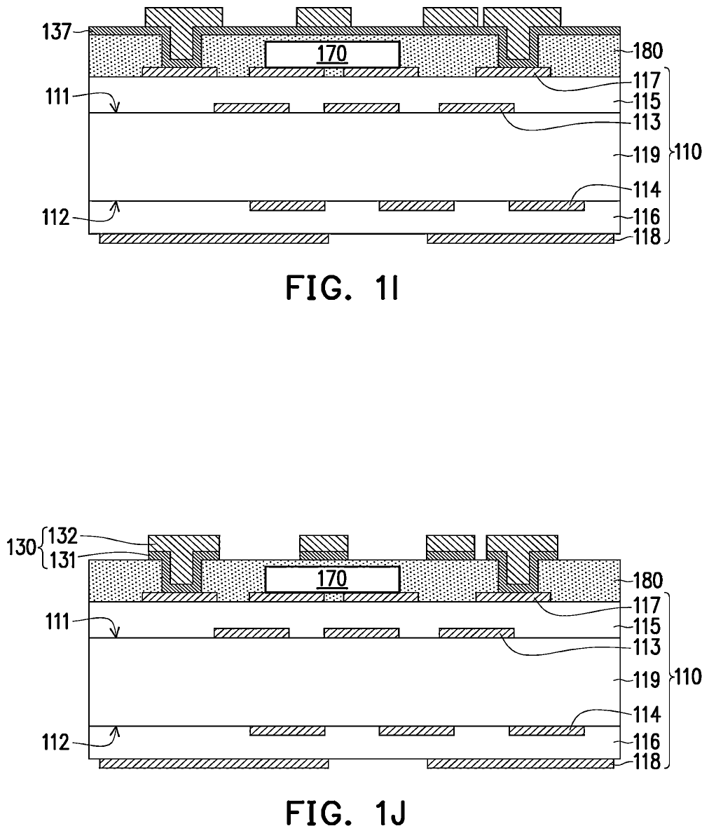

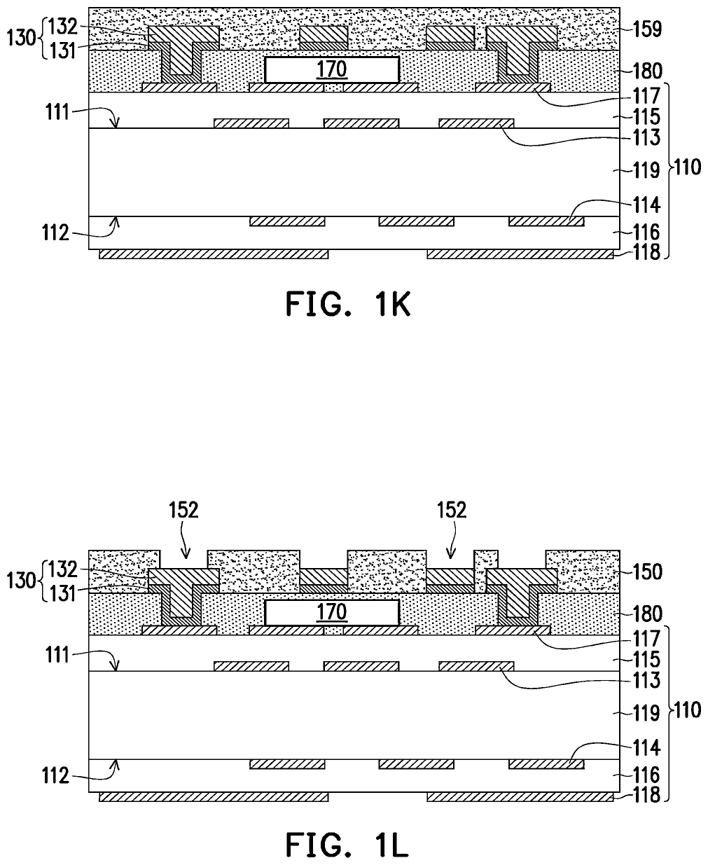

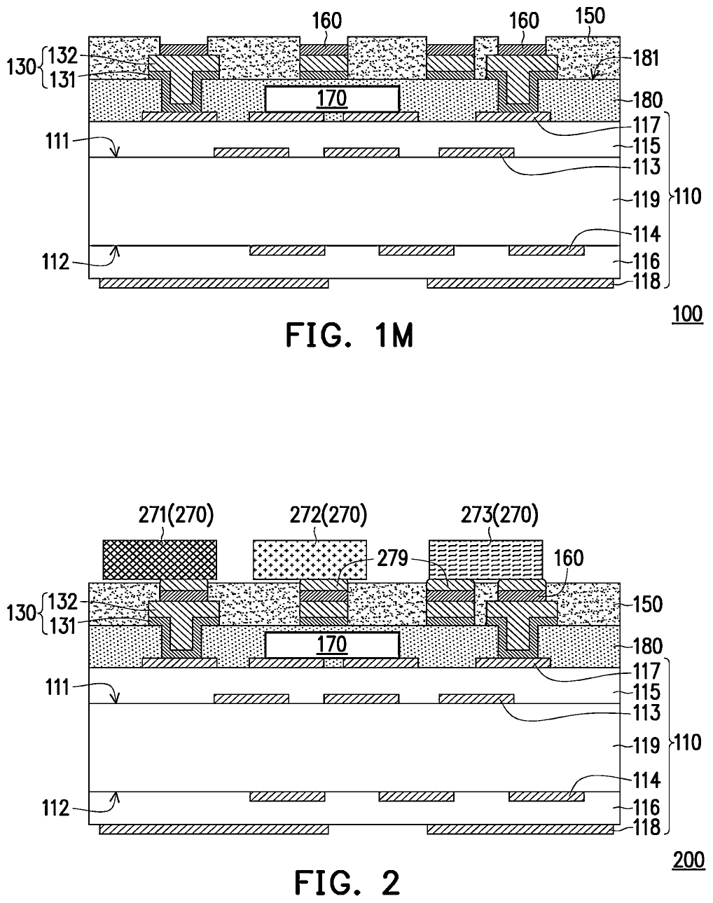

FIG. 1A to FIG. 1M are schematic side views of a portion of a manufacturing method of a circuit board according to an embodiment of the disclosure.

Referring to FIG. 1A, a substrate structure 110 is provided. The substrate structure 110 includes a substrate 119 and a circuit layer 117 disposed on the substrate 119.

In an embodiment, the substrate 119 may include a rigid substrate, but the disclosure is not limited thereto. The material of the rigid substrate includes, for example, glass, a glass fiber layer containing epoxy resin (e.g., a common FR4 substrate), bismaleimide triazine board (BT board) or other suitable hard boards, but the disclosure is not limited thereto. In an embodiment, the substrate structure 110 may be a or a rigid printed circuit board.

In an embodiment, the substrate 119 may include a flexible substrate, but the disclosure is not limited thereto. The material of the flexible substrate includes, for example, polyimide (PI), polyethylene terephthalate (PET) or other suitable flexible material, but the disclosure is not limited thereto. In an embodiment, the substrate structure 110 may be a flexible printed circuit board.

In an embodiment, a corresponding circuit layer (e.g., a circuit layer 113 or a circuit layer 117) may be disposed on a first surface 111 of the substrate 119. As shown in FIG. 1A, the circuit layer 113 and the circuit layer 117 may be disposed on the first surface 111 of the substrate 119. A corresponding insulating layer 115 may be disposed between the circuit layer 113 and the circuit layer 117. A corresponding circuit in of the circuit layer 113 and a corresponding circuit in the circuit layer 117 may be electrically connected via a conductive vias (not shown) penetrating the insulating layer 115 according to a design requirement.

In an embodiment, a corresponding circuit layer (e.g., a circuit layer 114 or a circuit layer 118) may be disposed on a second surface 112 of the substrate 119. As shown in FIG. 1A, the circuit layer 114 and the circuit layer 118 may be disposed on the second surface 112 of the substrate 119. A corresponding insulating layer 116 may be disposed between the circuit layer 114 and the circuit layer 118. A corresponding in of the circuit layer 114 and a corresponding circuit in the circuit layer 118 may be electrically connected via a conductive vias (not shown) penetrating the insulating layer 116 according to a design requirement.

In an embodiment, the substrate structure 110 as shown in FIG. 1A may be referred as a double-sided board, but the disclosure is not limited thereto. In an embodiment not shown, a substrate structure similar to the substrate structure 110 may be a single-sided board.

In an embodiment, the circuit layer (e.g., the circuit layer 113 and/or the circuit layer 117; or, the circuit layer 114 and/or the circuit layer 118) on a surface of the substrate 119 (e.g., at least one of the first surface 111 or the second surface 112) may be formed a build-up method or a subtraction method, which is not limited in the disclosure.

The number of layers of the circuit layer(s) on the first surface 111 and/or the second surface 112 is not limited in the disclosure. Additionally, if corresponding circuit layers (e.g., the circuit layer 113 and the circuit layer 114) are both disposed on the first surface 111 and the second surface 112 of the substrate 119, corresponding circuits in the aforementioned circuit layers respectively disposed on the first surface 111 and the second surface 112 of the substrate 119 may be electrically connected via a conductive vias (not shown) penetrating the substrate 119 according to a design requirement.

Referring to FIG. 1B, a chip 170 is disposed on the substrate structure 110 and electrically connected to the circuit layer 117. For clarity or simplicity, the circuit layer labelled as 117 may be referred as the “first circuit layer” subsequently.

In an embodiment, a portion of the first circuit layer 117 may be referred as a contact pad. The chip 170 may be disposed on the connection pad included in the first circuit layer 117 via flip chip bonding method.

The type or function of the chip 170 is not limited in the disclosure. For example, the chip 170 may include a memory chip, a logic chip or a suitable semiconductor chip.

Only one chip 170 is exemplary shown in FIG. 1B, but the disclosure is not limited thereto. On another cross-section not shown, there may be another chip or other chips that are the same or similar to the chip 170.

In an embodiment not shown, the chip 170 or at least one of the chips that are the same or similar to the chip 170 could be replaced with a passive device (e.g., a multi-layer ceramic capacitor (MLCC), but not limited to).

Referring to FIG. 1C, an insulating film 189 is disposed on the substrate 119 to cover the first circuit layer 117 and the chip 170.

In an embodiment, the insulating film may be a photosensitive dry-film. In an embodiment, the photosensitive dry film may be formed, for example, through a photosensitive resin composition.

In an embodiment, the insulating film 189 may be laid on the substrate 119 at one time.

In an embodiment, the insulating film 189 is disposed on the substrate 119 directly and/or via a one-time process. For example, the insulating film 189 could be directly picked up by people or a tool (e.g., a jig, a clamp, or a sucker) without being in contact with the substrate 119 or any film and/or layer disposed thereon; then, the aforementioned insulating film 189 directly picked up by people or the tool is directly laid on the substrate 119 and is in contact with the substrate 119 or the film or the layer disposed thereon.

In an embodiment, the insulating film 189 is an unpatterned film. For example, the insulating film 189 is a film without any hole or opening. For example, in a plan view, similar to a common A3/A4 printable paper, the edge of the insulating film 189 forms a closed contour, and there is no hole or opening inside the aforementioned closed contour. In this way, the insulating film 189 may be easily laid on the substrate 119 at one time or directly.

For example, in a process of using a large-sized substrate structure (e.g., a circuit board), if a corresponding unpatterned film (e.g., another insulating films different from the aforementioned insulating film 189) is formed on the aforementioned large-sized substrate structure by coating polymer material and then curing, the quality of the aforementioned unpatterned film (e.g., another insulating films different from the aforementioned insulating film 189) may be poorer due to the unevenness or difficulty of the aforementioned coating step (e.g., when the overall coating has not been completed, a portion of the coated polymer material may have been partially cured). Additionally, not only a corresponding inspection (such as: quality inspection) may be performed to the unpatterned film (e.g., the insulating film 189 or an insulating film 189 similar thereof) before performing the laying process, but also the complexity and/or the difficulty of manufacturing method may be reduced (e.g., without coating polymer material on the substrate 119 and is in contact with the substrate 119 or the film or the layer disposed thereon). As such, the quality of the manufacturing method and/or the product may be improved by the one-time process.

Referring to FIG. 1C to FIG. 1D, the insulating film 189 disposed on the substrate 119 is pressed. For a clearer definition, the insulating film before being pressed is labeled as 189 as shown in FIG. 1C, the insulating film after being pressed is labeled as 188 as shown in FIG. 1D or other figures similar thereof. The top surface (e.g., the surface of the insulating film 188 farthest from the substrate structure 110) 181 of the insulating film 188 is flatter than the top surface (e.g., the surface of the insulating film 189 corresponding to the top surface 181) of the insulating film 189.

In an embodiment, the insulating film 189 disposed on the substrate 119 may be directly pressed by a pressing piece 80.

In an embodiment not shown, the insulating film 189 disposed on the substrate 119 may be pressed by a roller in a rolling manner.

In an embodiment, the insulating film 189 disposed on the substrate 119 may be heated correspondingly while being pressed.

In an embodiment, the pressing piece 80 may include a corresponding heating device (e.g., an electric heating device). The insulating film 189 disposed on the substrate 119 may be heated and directly pressed through a pressing piece with a hot-pressing function.

In an embodiment not shown, the insulating film 189 disposed on the substrate 119 may be heated and pressed by a hot-pressing roller.

In an embodiment, when the insulating film 189 is disposed on the substrate 119 directly or via the one-time process to cover the first circuit layer 117 and the chip 170 (e.g., as shown in FIG. 1C), the insulating film 189 and the first circuit layer 117 and/or the insulating film 189 and the chip 170 may be in contact with each other by van der Waals force and/or electrostatic force; as such, there may be a gap and/or a gas bubble therebetween. Therefore, the gap therebetween may be reduced and/or the gas bubble therebetween may be pressed out by performing the aforementioned pressing step.

In an embodiment, the step of deposing the insulating film 189 on the substrate 119 directly or via the one-time process (e.g., as shown in FIG. 1C) may be performed under room pressure (e.g., 1 atmosphere), and the pressing step (e.g., as shown in FIG. 1D) may be performed under a lower pressure (e.g., less than 1 atmosphere). For example, the substrate structure 110 and the insulating film 189 disposed thereon may be placed in a chamber; then, the gas in the chamber is pumped out for reducing the gas pressure in the chamber; and, during or after the pumping process, the pressing step may be performed. As such, the gas bubble (if any) between the insulating film 189 and the first circuit layer 117 and/or the insulating film 189 and the chip 170 may be pressed out more easily.

In addition, the insulating film 188 disposed on the substrate 119 has a flatter top surface 181 after the pressing is performed. In an embodiment, the surface roughness of the top surface 181 of the insulating film 188 may less than 500 micrometers (μm).

In an embodiment, through the flat top surface 181 of the insulating film 188, an element, a device and/or a film layer may be disposed or covered thereon easily. As such, the process window of the subsequent process or the overall process may be improved.

In an embodiment, through the flat top surface 181 of the insulating film 188, the quality of subsequent processes may be improved. For example, if a photolithography process may be performed to the insulating film 188, the quality of the exposing step (e.g., alignment accuracy and/or alignment) may be improved since the top surface 181 of the insulating film 188 is a flat surface. As such, a smaller opening size or space size (e.g., less than or equal to 10 μm) may be formed, and a fine via or fine pitch may be further formed.

Referring to FIG. 1D to FIG. 1E, after the aforementioned pressing step, a portion of the insulating film 188 (as shown in FIG. 1D) is removed for forming an insulating layer 180 (as shown in FIG. 1E) having an insulating opening 182. A portion of the first circuit layer 117 is exposed by the insulating opening 182. For a clearer definition, the unpatterned insulating film is labeled as 188 as shown in FIG. 1D, the patterned insulating layer (e.g., having the insulating opening 182) is labeled as 180 as shown in FIG. 1E. For clarity or simplicity, the patterned insulating layer labelled as 180 may be referred as the “first insulating layer” subsequently.

In an embodiment, a portion of the insulating film 188 may be removed by a removing process including a photolithography process.

In an embodiment, the insulating film 188 may for example, be formed into a corresponding patterned insulating film layer through a corresponding process (e.g., a pre-baking step, an exposing step, a developing step and a post-baking step).

Referring to FIG. 1F, a first conductive layer 137 is formed and disposed on the substrate 119. The first conductive layer 137 covers the first insulating layer 180 having the insulating opening 182 and the portion of the first circuit layer 117 exposed by the insulating opening 182.

In an embodiment, the first conductive layer 137 may be formed by a sputtering process.

In an embodiment, the first conductive layer 137 at least partially covers a sidewall 183 (as shown in FIG. 1E) of the insulating opening 182 (as shown in FIG. 1E).

In an embodiment, the first conductive layer 137 may be referred as a plating seed layer.

Referring to FIG. 1G, a second insulating layer 140 is formed on the first conductive layer 137.

In the embodiment, the first conductive layer 137 includes a first portion 133 and a second portion 135. The first portion 133 does not overlap the second insulating layer 140, and the second portion 135 overlaps the second insulating layer 140.

The first portion 133 does not overlap the second insulating layer 140, and the second portion 135 overlaps the second insulating layer 140.

In an embodiment, the second insulating layer 140 may be referred as a mask layer.

In an embodiment, the second insulating layer 140 may be a patterned dry film.

In an embodiment, the material of the second insulating layer 140 may be different form the material of the first insulating layer 180. For example, in a specific wet etchant, the etching rate of the second insulating layer 140 may be greater than the etching rate of the first insulating layer 180.

Referring to FIG. 1H, a second conductive layer 132 is formed and disposed on the first portion 133. The thickness of the second conductive layer 132 is greater than the thickness of the first conductive layer 137. In an embodiment, the thickness of the second conductive layer 132 may be 5 times to 500 times the thickness of first conductive layer 137. In an embodiment, the thickness of the second conductive layer 132 may be 10 times to 100 times the thickness of first conductive layer 137.

In an embodiment, the second conductive layer may be formed by an electroplating process. In an embodiment, the second conductive layer 132 may be referred as an electroplating layer.

In an embodiment, after the aforementioned electroplating process is completed, a corresponding planarization process may be performed on the conductive layer formed by the aforementioned electroplating process.

Referring to FIG. 1H to FIG. 1I, the second insulating layer 140 (as shown in FIG. 1H) is removed.

In an embodiment, the second insulating layer 140 may be removed by a wet etching process or an ashing process.

Referring to FIG. 1I to FIG. 1J, the second portion 135 (as shown in FIGS. 1H or 1I) of the first conductive layer 137 is removed. In an embodiment, the second portion 135 of the first conductive layer 137 may be removed by a wet etching process.

In an embodiment, in the process of removing the second portion 135, a portion of the first portion 133 and/or a portion of the second conductive layer 132 may also be slightly removed.

For a clearer definition, the unpatterned first conductive layer (e.g., including the first portion 133 and the second portion 135) is labeled as 137 as shown in FIG. 1I, and the patterned first conductive layer (e.g., at least the second portion 135 has been removed) is labeled as 131 as shown in FIG. 1J.

After the second portion 135 being removed, the remaining first portion 133 and the second conductive layer 132 may be constituted a second circuit layer 130. That is, the second circuit layer 130 may include the first conductive layer 131 and the second conductive layer 132.

Referring to FIG. 1K, a solder resist material 159 is formed and disposed on the second circuit layer 130.

In an embodiment, the solder resist material 159 may include a liquid photoimageable solder mask (LPSM). In an embodiment, the liquid solder resist material 159 may be formed on the substrate structure 110 by a coating process.

In an embodiment, the solder resist material 159 may be referred as a solder mask green ink, but the disclosure is not limited thereto.

Referring to FIG. 1K to FIG. 1L, a portion of the solder resist material 159 (as shown in FIG. 1K) is removed for forming a solder resist layer 150 (as shown in FIG. 1L) having a solder resist opening 152. A portion of the second circuit layer 130 is exposed by the solder resist opening 152.

In an embodiment, a portion of the solder resist material 159 may be removed by an etching process or a suitable patterning process to at least expose a portion of the second circuit layer 130. Then, the solder resist material 159 disposed on the substrate structure 110 may be may be formed into the solder resist layer 150 having the solder resist opening 152 by an appropriate curing process (e.g., a photocuring process and/or a thermal curing process).

Referring to FIG. 1M, in an embodiment, a conductive protective layer 160 may be formed on the portion of the second circuit layer 130 exposed by the solder resist opening 152. In an embodiment, the conductive protective layer 160 may include a plurality of stacked conductive layers. For example, the conductive protective layer 160 may include an ENIG (Electroless Nickel Immersion Gold) layer.

After the above process, the circuit board 100 of the embodiment may be substantially formed. The circuit board 100 has a chip 170 embedded therein; therefore, the circuit board 100 may be referred as a chip-embedded circuit board. The circuit board 100 includes a substrate 119, a first circuit layer 117, a chip 170, an insulating layer 180, a second circuit layer 130, and a solder resist layer 150. The first circuit layer 117 is disposed on the substrate 119. The chip 170 is disposed on the substrate 119. The chip 170 is electrically connected to the first circuit layer 117. The insulating layer 180 is disposed on the substrate 119. The insulating layer 180 covers the chip 170 and a portion of the first circuit layer 117. The second circuit layer 130 is disposed on the insulating layer 180. The second circuit layer 130 penetrates a portion of the insulating layer 180 to electrically connect the first circuit layer 117. The solder resist layer 150 is disposed on the substrate 119. The solder resist layer 150 covers a portion of the second circuit layer 130.

In an embodiment, the top surface 181 of the insulating layer is a flat surface.

In an embodiment, the second circuit layer 130 includes a first conductive layer 131 (e.g., corresponding to the first portion 133 of the first conductive layer 137 in the process) and a patterned second conductive layer 132. The patterned first conductive layer 131 is disposed between the insulating layer 180 and the second conductive layer 132.

The circuit board 100 of the embodiment may be applied or further processed as required, which is not limited in the disclosure. For example, the circuit board 100 of the embodiment may be applied to a manufacture method of a light emitting module or as a portion of a light emitting module.

FIG. 2 is schematic a side view of a portion of a manufacturing method of a light emitting module according to an embodiment of the disclosure. In the embodiment, the circuit board used is the circuit board 100 of the previous embodiment (e.g., a chip-embedded circuit board). As similar components with the same reference numbers have same or similar functions, materials, or forming techniques, the description thereof is omitted hereinafter.

Referring to FIG. 2, a light-emitting device 270 is disposed on the circuit board 100 has a chip 170 embedded therein. The light-emitting device 270 is electrically connected to the second circuit layer 130.

Only three light-emitting devices 270 are exemplary shown in FIG. 2, but the disclosure is not limited thereto. On another cross-section not shown, there may be another light-emitting device or other light-emitting devices that are the same or similar to the light-emitting device 270.

In an embodiment, the light-emitting device 270 may be electrically connected to a portion of the second circuit layer 130 (e.g., a connection pad included in the second circuit layer 130) via a corresponding conductive connector 279.

In an embodiment, the conductive connector 279 may include solder, but the disclosure is not limited thereto.

In an embodiment, the light-emitting device 270 may be electrically connected to the chip 170 via a corresponding circuit.

In an embodiment, the chip 170 may include a display driver IC (DDIC).

On another cross-section not shown, there may be another conductive connector or other conductive connectors that are the same or similar to the conductive connector 279.

After the above process, the light emitting module 200 of the embodiment may be substantially formed. The light emitting module 200 includes the circuit board 100 and the light-emitting device 270. The light-emitting device 270 is disposed on the circuit board 100 and electrically connected to the second circuit layer 130 of the circuit board 100.

The light-emitting device 270 may include a light-emitting device 271, a light-emitting device 272 and/or a light-emitting device 273. The light-emitting device 271, the light-emitting device 272 and/or the light-emitting device 273 may have different light-emitting colors from each other. For example, one of the light-emitting device 271, the light-emitting device 272 and the light-emitting device 273 may emit red light; another of the light-emitting device 271, the light-emitting device 272 and the light-emitting device 273 may emit green light; and, another one of the light-emitting device 271, the light-emitting device 272 and the light-emitting device 273 may emit blue light.

In an embodiment, the light-emitting device 270 may be a light emitting diode (LED). For example, the light-emitting device 270 may be a micro light emitting diode (μLED).

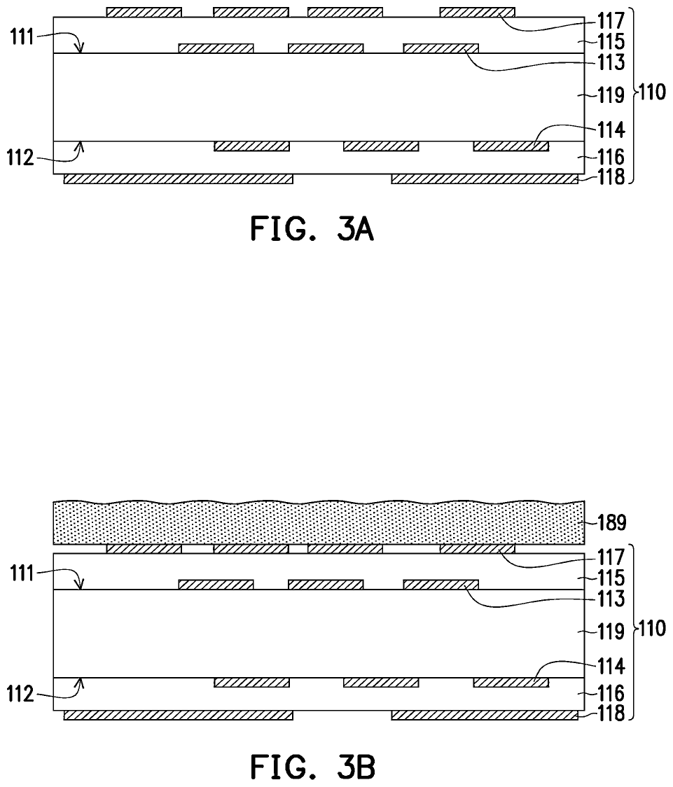

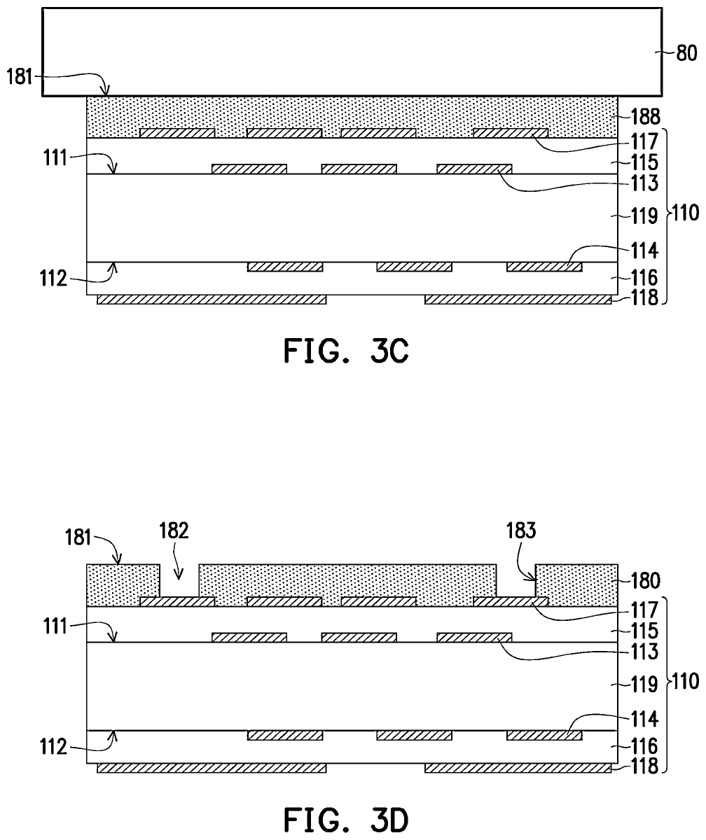

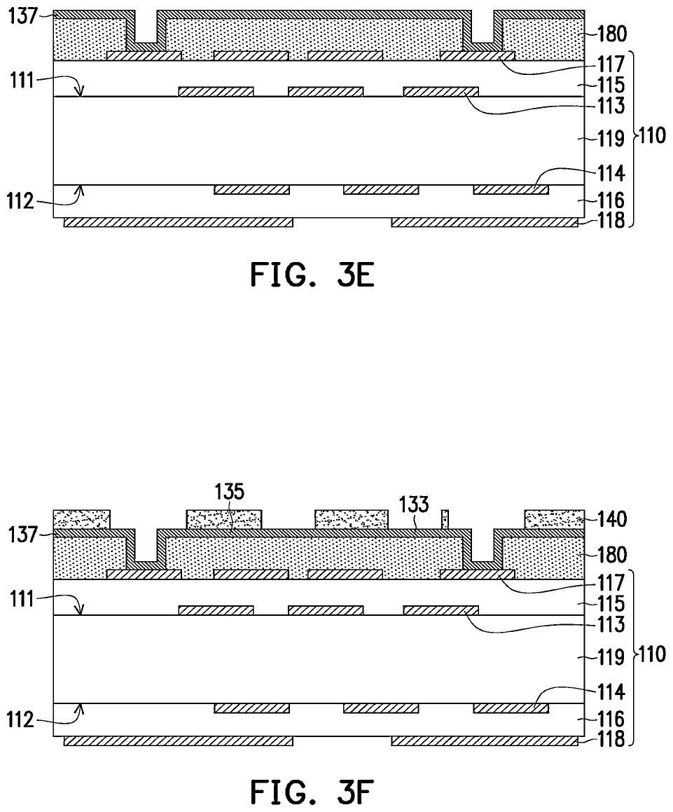

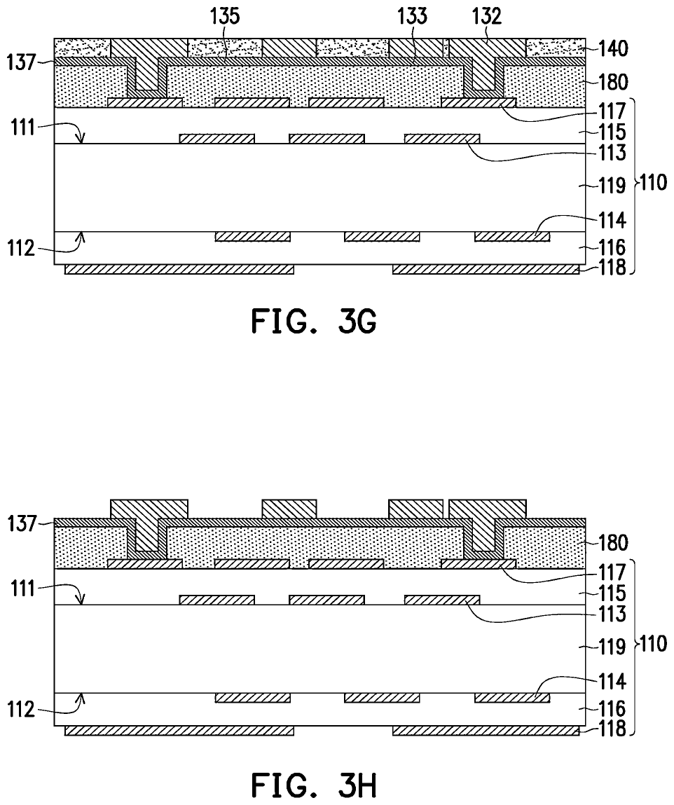

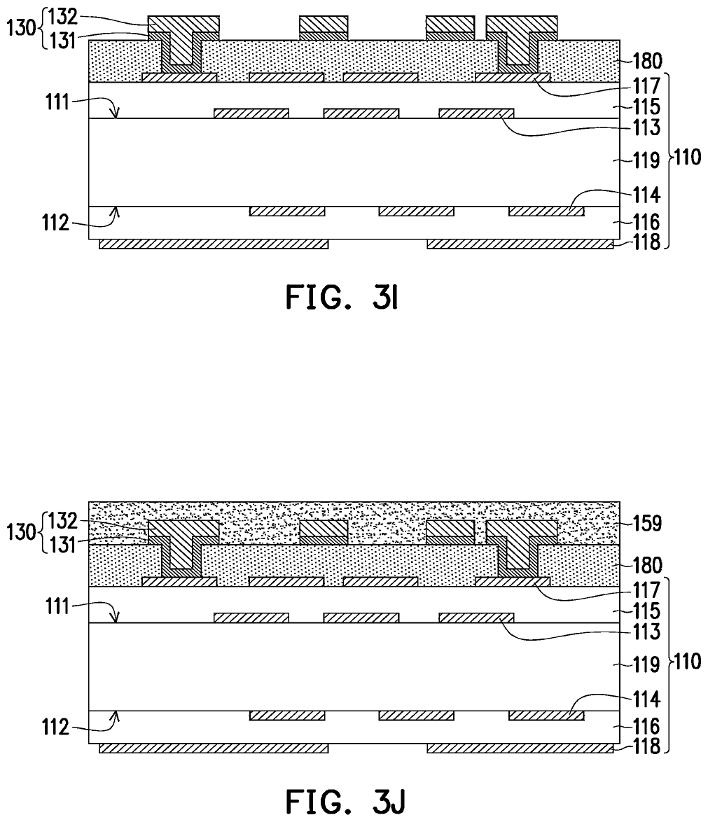

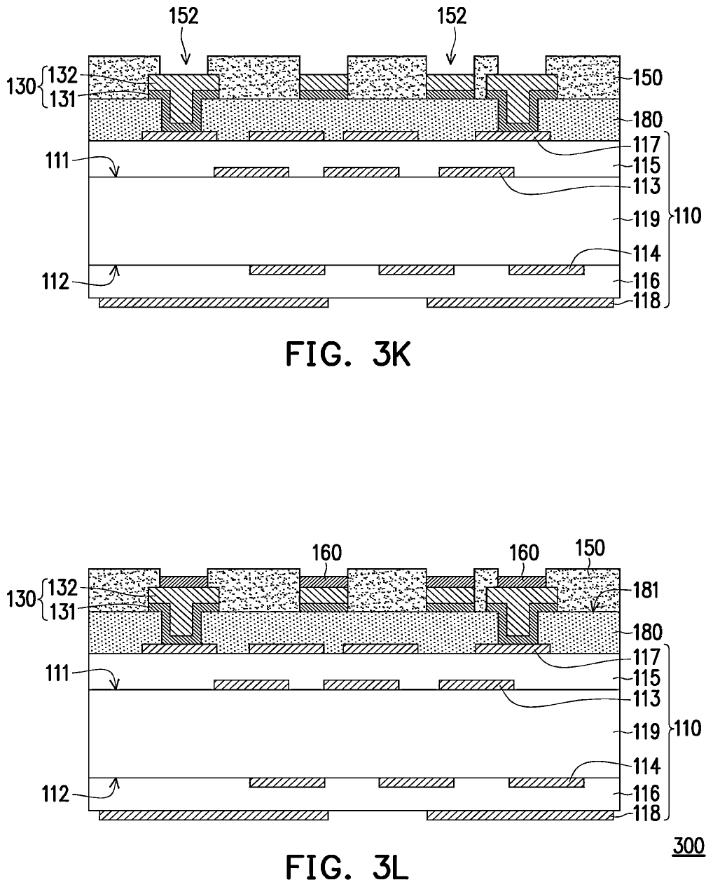

FIG. 3A to FIG. 3L are schematic side views of a portion of a manufacturing method of a circuit board according to an embodiment of the disclosure. The manufacturing method of the circuit board 300 (as shown in FIG. 3L) of the present embodiment is similar to the manufacturing method of the circuit board 100 (as shown in FIG. 1M). As similar components with the same reference numbers have similar functions, materials, or forming techniques, the description thereof is omitted hereinafter.

Referring to FIG. 3A, a substrate structure 110 is provided. The substrate structure 110 includes a substrate 119 and a circuit layer 117 disposed thereon.

In an embodiment, a corresponding circuit layer (e.g., the circuit layer 113 or the circuit layer 117) may be disposed on the first surface 111 of the substrate 119; and/or a corresponding circuit layer (e.g., the circuit layer 114 or the circuit layer 118) may be disposed on the second surface 112 of the substrate 119.

For clarity or simplicity, the circuit layer labelled as 117 may be referred as the “first circuit layer” subsequently.

In an embodiment, an electronic device may be disposed on the substrate structure 110 and electrically connected to the first circuit layer 117 as required.

Referring to FIG. 3B, an insulating film 189 is disposed on the substrate 119 to cover the first circuit layer 117.

In an embodiment, the insulating film may be a photosensitive dry-film. In an embodiment, the photosensitive dry film may be formed, for example, through a photosensitive resin composition.

In an embodiment, the insulating film 189 may be laid on the substrate 119 at one time.

In an embodiment, the insulating film 189 is disposed on the substrate 119 directly and/or via a one-time process. In this way, the insulating film 189 may be easily laid on the substrate 119 at one time or directly.

For example, in a process of using a large-sized substrate structure (e.g., a circuit board), if a corresponding unpatterned film (e.g., another insulating films different from the aforementioned insulating film 189) is formed on the aforementioned large-sized substrate structure by coating polymer material and then curing, the quality of the aforementioned unpatterned film (e.g., another insulating films different from the aforementioned insulating film 189) may be poorer due to the unevenness or difficulty of the aforementioned coating step (e.g., when the overall coating has not been completed, a portion of the coated polymer material may have been partially cured). Additionally, not only a corresponding inspection (such as: quality inspection) may be performed to the unpatterned film (e.g., the insulating film 189 or an insulating film 189 similar thereof) before performing the laying process, but also the complexity and/or the difficulty of manufacturing method may be reduced (e.g., without coating polymer material on the substrate 119 and is in contact with the substrate 119 or the film or the layer disposed thereon).

As such, the quality of the manufacturing method and/or the product may be improved by the one-time process.

Referring to FIG. 3B to FIG. 3C, performing a same or similar step as shown in FIG. 1C to FIG. 1D, the insulating film 189 disposed on the substrate 119 is pressed. For a clearer definition, the insulating film before being pressed is labeled as 189 as shown in FIG. 3B, the insulating film after being pressed is labeled as 188 as shown in FIG. 1C or other figures similar thereof. The top surface of the insulating film 188 is flatter than the top surface of the insulating film 189.

In an embodiment, the insulating film 189 disposed on the substrate 119 may be directly pressed by a pressing piece 80.

In an embodiment not shown, the insulating film 189 disposed on the substrate 119 may be pressed by a roller in a rolling manner.

In an embodiment, the insulating film 189 disposed on the substrate 119 may be heated correspondingly while being pressed.

In an embodiment, the pressing piece 80 mayinclude a corresponding heating device (e.g., an electric heating device). The insulating film 189 disposed on the substrate 119 may be heated and directly pressed through a pressing piece with a hot-pressing function.

In an embodiment not shown, the insulating film 189 disposed on the substrate 119 may be heated and pressed by a hot-pressing roller.

In an embodiment, when the insulating film 189 is disposed on the substrate 119 directly or via the one-time process to cover the first circuit layer 117 (e.g., as shown in FIG. 3B), the insulating film 189 and the first circuit layer 117 may be in contact with each other by van der Waals force and/or electrostatic force; as such, there may be a gap and/or an gas bubble therebetween. Therefore, the gap therebetween may be reduced and/or the gas bubble therebetween may be pressed out by performing the aforementioned pressing step.

In an embodiment, the step of deposing the insulating film 189 on the substrate 119 directly or via the one-time process (e.g., as shown in FIG. 3B) may be performed under room pressure (e.g., 1 atmosphere), and the pressing step (e.g., as shown in FIG. 3C) may be performed under a lower pressure (e.g., less than 1 atmosphere). For example, the substrate structure 110 and the insulating film 189 disposed thereon may be placed in a chamber; then, the gas in the chamber is pumped out for reducing the gas pressure in the chamber; and, during or after the pumping process, the pressing step may be performed. As such, the gas bubble (if any) between the insulating film 189 and the first circuit layer 117 may be pressed out more easily.

In addition, the insulating film 188 disposed on the substrate 119 has a flatter top surface 181 after the pressing is performed. In an embodiment, the surface roughness of the top surface 181 of the insulating film 188 may less than 500 μm.

In an embodiment, through the flat top surface 181 of the insulating film 188, an element, a device and/or a film layer may be disposed or covered thereon easily. As such, the process window of the subsequent process or the overall process may be improved.

In an embodiment, through the flat top surface 181 of the insulating film 188, the quality of subsequent processes may be improved. For example, if a photolithography process may be performed to the insulating film 188, the quality of the exposing step (e.g., alignment accuracy and/or alignment) may be improved since the top surface 181 of the insulating film 188 is a flat surface. As such, a smaller opening size or space size (e.g., less than or equal to 10 μm) may be formed, and a fine via or fine pitch may be further formed.

Referring to FIG. 3C to FIG. 3D, performing a same or similar step as shown in FIG. 1D to FIG. 1E, after the aforementioned pressing step, a portion of the insulating film 188 (as shown in FIG. 3C) is removed for forming an insulating layer 180 (as shown in FIG. 3D) having an insulating opening 182.

Referring to FIG. 3E, performing a same or similar step as shown in FIG. 1F, a first conductive layer 137 is disposed on the substrate 119. The first conductive layer 137 covers the first insulating layer 180 having the insulating opening 182 and the portion of the first circuit layer 117 exposed by the insulating opening 182.

Referring to FIG. 3F, performing a same or similar step as shown in FIG. 1G, a second insulating layer 140 is formed on the first conductive layer 137. The first conductive layer 137 includes a first portion 133 and a second portion 135. The first portion 133 does not overlap the second insulating layer 140, and the second portion 135 overlaps the second insulating layer 140.

Referring to FIG. 3G, performing a same or similar step as shown in FIG. 1H, a second conductive layer 132 is formed and disposed on the first portion 133. The thickness of the second conductive layer 132 is greater than the thickness of the first conductive layer 131.

Referring to FIG. 3G to FIG. 3H, performing a same or similar step as shown in FIG. 1H to FIG. 1I, the second insulating layer 140 (as shown in FIG. 3G) is removed.

Referring to FIG. 3H to FIG. 3I, performing a same or similar step as shown in FIG. 1I to FIG. 1J, the second portion 135 (as shown in FIGS. 3G or 3H) of the first conductive layer 137 is removed.

For a clearer definition, the unpatterned first conductive layer (e.g., including the first portion 133 and the second portion 135) is labeled as 137 as shown in FIG. 3H, and the patterned first conductive layer (e.g., at least the second portion 135 has been removed) is labeled as 131 as shown in FIG. 3I

After the second portion 135 being removed, the remaining first portion 133 and the second conductive layer 132 may be constituted a second circuit layer 130. That is, the second circuit layer 130 may include the first conductive layer 131 and the second conductive layer 132.

Referring to FIG. 3J, performing a same or similar step as shown in FIG. 1K, a solder resist material 159 is formed and disposed on the second circuit layer 130.

Referring to FIG. 3J to FIG. 3K, performing a same or similar step as shown in FIG. 1K to FIG. 1L, a portion of the solder resist material 159 (as shown in FIG. 3J) is removed for forming a solder resist layer 150 (as shown in FIG. 3K) having a solder resist opening 152. A portion of the second circuit layer 130 is exposed by the solder resist opening 152.

Referring to FIG. 3L, performing a same or similar step as shown in FIG. 1M, a conductive protective layer 160 may be formed on the portion of the second circuit layer 130 exposed by the solder resist opening 152.

After the above process, the circuit board 300 of the embodiment may be substantially formed. The circuit board 300 includes a substrate 119, a first circuit layer 117, an insulating layer 180, a second circuit layer 130, and a solder resist layer 150. The first circuit layer 117 is disposed on the substrate 119. The insulating layer 180 is disposed on the substrate 119. The insulating layer 180 covers a portion of the first circuit layer 117. The second circuit layer 130 is disposed on the insulating layer 180. The second circuit layer 130 penetrates a portion of the insulating layer 180 to electrically connect the first circuit layer 117. The solder resist layer 150 is disposed on the substrate 119. The solder resist layer 150 covers a portion of the second circuit layer 130.

The circuit board 300 of the embodiment may be applied or further processed as required, which is not limited in the disclosure. For example, the circuit board 300 of the embodiment may be applied to a manufacture method of a light emitting module or as a portion of a light emitting module.

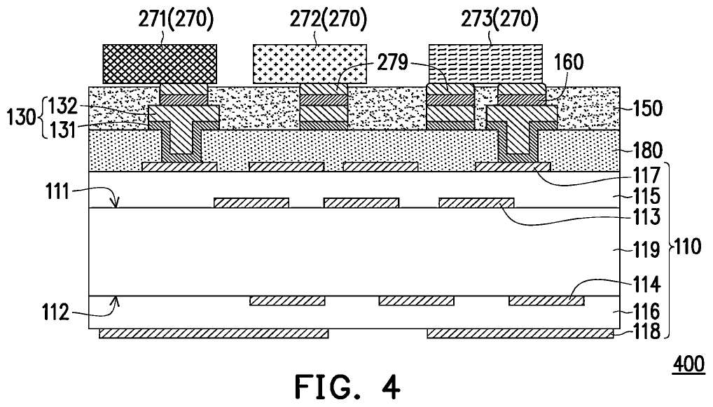

FIG. 4 is schematic a side view of a portion of a manufacturing method of a light emitting module according to an embodiment of the disclosure. In the embodiment, the circuit board used is the circuit board 300 of the previous embodiment (e.g., a chip-embedded circuit board). As similar components with the same reference numbers have same or similar functions, materials, or forming techniques, the description thereof is omitted hereinafter.

Referring to FIG. 4, a light-emitting device 270 is disposed on the circuit board 300. The light-emitting device 270 is electrically connected to the second circuit layer 130.

Only three light-emitting devices 270 are exemplary shown in FIG. 4, but the disclosure is not limited thereto. On another cross-section not shown, there may be another light-emitting device or other light-emitting devices that are the same or similar to the light-emitting device 270.

In an embodiment, the light-emitting device 270 may be electrically connected to a portion of the second circuit layer 130 (e.g., a connection pad included in the second circuit layer 130) via a corresponding conductive connector 279.

On another cross-section not shown, there may be another conductive connector or other conductive connectors that are the same or similar to the conductive connector 279.

After the above process, the light emitting module 400 of the embodiment may be substantially formed. The light emitting module 400 includes the circuit board 300 and the light-emitting device 270. In an embodiment, the light-emitting device 270 may include a light-emitting device 271, a light-emitting device 272 and/or a light-emitting device 273. The light-emitting device 271, the light-emitting device 272 and/or the light-emitting device 273 may have different light-emitting colors from each other.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a circuit board, comprising:
providing a substrate structure, wherein the substrate structure comprises a substrate and a first circuit layer disposed on the substrate;
forming a first insulating layer on the substrate, wherein the first insulating layer has an insulating opening exposing a portion of the first circuit layer;
forming a first conductive layer on the substrate, wherein the first conductive layer covers the first insulating layer having the insulating opening and the portion of the first circuit layer exposed by the insulating opening;
forming a second insulating layer on the first conductive layer, wherein the first conductive layer has a first portion and a second portion, the first portion does not overlap the second insulating layer, and the second portion overlaps the second insulating layer;
forming a second conductive layer on the first portion;
removing the second insulating layer and the second portion, the first portion and the second conductive layer forming a second circuit layer; and
forming a solder resist layer on the second circuit layer, wherein the solder resist layer has a solder resist opening exposing a portion of the second circuit layer.

2. The manufacturing method of the circuit board according to claim 1, wherein a step of forming the first insulating layer having the insulating opening comprising:
disposing an insulating film on the substrate to cover the first circuit layer; and
removing a portion of the insulating film to form the first insulating layer having the insulating opening.

3. The manufacturing method of the circuit board according to claim 2, wherein the insulating film is laid on the substrate at one time.

4. The manufacturing method of the circuit board according to claim 2, wherein the step of forming the first insulating layer having the insulating opening comprising:
pressing the insulating film disposed on the substrate before removing the portion of the insulating film to form the first insulating layer having the insulating opening.

5. The manufacturing method of the circuit board according to claim 2, a step of removing the portion of the insulating film comprising:
performing a photolithography process.

6. The manufacturing method of the circuit board according to claim 2, wherein the first conductive layer is formed by including a sputtering process, and the second conductive layer is formed by including an electroplating process.

7. The manufacturing method of the circuit board according to claim 6, wherein the first conductive layer at least partially covers a sidewall of the insulating opening.

8. The manufacturing method of the circuit board according to claim 1, further comprising:
disposing a chip on the substrate structure and electrically connecting the first circuit layer.

9. The manufacturing method of the circuit board according to claim 8, wherein a step of forming the first insulating layer having the insulating opening comprising:
disposing an insulating film on the substrate to cover the first circuit layer and the chip; and
removing a portion of the insulating film to form the first insulating layer having the insulating opening.

10. A circuit board, comprising:
a substrate;
a first circuit layer disposed on the substrate;
a first insulating layer disposed on the substrate and covering a portion of the first circuit layer;
a second circuit layer disposed on the first insulating layer and penetrating a portion of the first insulating layer to electrically connect the first circuit layer; and
a solder resist layer disposed on the substrate and covering a portion of the second circuit layer.

11. The circuit board according to claim 10, wherein a top surface of the first insulating layer is a flat surface.

12. The circuit board according to claim 10, wherein the second circuit layer comprises a patterned first conductive layer and a patterned second conductive layer, and the patterned first conductive layer is disposed between the first insulating layer and the patterned second conductive layer.

13. The circuit board according to claim 10, further comprising:
a chip disposed on the substrate and electrically connecting the first circuit layer, wherein the first insulating layer further covers the chip.

14. A light emitting module, comprising:
a substrate;
a first circuit layer disposed on the substrate;
a first insulating layer disposed on the substrate and covering a portion of the first circuit layer;
a second circuit layer disposed on the first insulating layer and penetrating a portion of the first insulating layer to electrically connect the first circuit layer;
a solder resist layer disposed on the substrate and covering a portion of the second circuit layer; and
a light-emitting device disposed on the substrate and electrically connected to the second circuit layer.

15. The light emitting module according to claim 14, further comprising:
a chip disposed on the substrate and electrically connecting the first circuit layer, wherein the first insulating layer further covers the chip.
